(19) United States
(12) Patent Application Publication
(10) Pub. No.: US 2010/0230281 A1
(43) Pub. Date: Sep. 16, 2010

(54) THIN FILM FORMING APPARATUS

(75) Inventors: Jeonghee Park, Hwaseong-si (KR); Yongho Ha, Hwaseong-si (KR); Hyeyoung Park, Seongnam-si (KR); Hyun-Suk Kwon, Seoul (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/723,318

(22) Filed: Mar. 12, 2010

(30) Foreign Application Priority Data
Mar. 16, 2009 (KR) 10-2009-0022308

(51) Int. Cl. C23C 14/34; C23C 14/00

(52) U.S. Cl. 204/298.08; 204/298.37

(57) ABSTRACT

Provided are a thin film forming apparatus and a thin film forming method. The thin film forming apparatus comprises a first electrode provided for etching a thin film formed on the substrate, a second electrode provided for forming a plasma in the internal space, a third electrode provided for focusing the plasma, and a control unit controlling a voltage to be applied to the first through third electrodes.

### CROSS-REFERENCE TO RELATED APPLICATIONS

This U.S. non-provisional patent application claims priority under 35 U.S.C. §119 to Korean Patent Application 10-2009-0022308, filed on Mar. 16, 2009, the entire contents of which are hereby incorporated by reference.

### BACKGROUND

The present disclosure herein relates to a thin film forming apparatus and a thin film forming method, and more particularly, to a thin film forming apparatus and a thin film forming method thereof, which can improve deposition efficiency of a thin film.

Generally, a process of fabricating a semiconductor comprises a thin film forming process. The thin film forming process may be executed using various kinds of deposition apparatuses. For instance, the thin film may be formed on a semiconductor substrate using, for example, Physical Vapor Deposition (PVD) apparatus, Chemical Vapor Deposition (CVD) apparatus, and Atomic Layer Deposition (ALD) apparatus. A PVD apparatus can execute processes at a low temperature compared to a CVD apparatus and an ALD apparatus, but it may form a thin film having poor step coverage. Accordingly, it is unsuitable to form the thin film on contact holes and trenches having large aspect ratio using a PVD apparatus. On the other hand, a CVD apparatus and an ALD apparatus can form a thin film having good step coverage compared to a PVD apparatus. However, since a CVD apparatus and an ALD apparatus execute processes at a high temperature, it may be difficult to use in processes in which a low temperature process is required.

### SUMMARY

The present disclosure is to provide a thin film forming apparatus, which can effectively form a thin film on a substrate, and a thin film forming method thereof.

The present disclosure is also to provide a thin film forming apparatus, which can form a thin film having good step coverage at a low temperature, and a thin film forming method thereof.

Embodiments of the inventive concept provide a thin film forming apparatus comprising: a chamber having an internal space configured to execute a thin film forming process on a substrate; a first electrode provided for etching a thin film formed on the substrate; a second electrode provided for forming a plasma in the internal space; a third electrode provided for focusing the plasma; and a control unit controlling a voltage to be applied to the first through third electrodes.

In some embodiments, the chamber may comprise an upper wall, a lower wall facing the upper wall, and a sidewall connecting the upper wall to the lower wall, the first electrode may be disposed on the lower wall to load the substrate, the second electrode may be disposed on the upper wall, and the third electrode may be disposed on the sidewall.

In some embodiments, the thin film forming apparatus may further comprise first through third applying sections connected to the first through third electrodes, respectively, to apply the voltage to the first through third electrodes. The control unit may independently control each of the first through third applying sections.

In some embodiments, a thin film may be deposited on a substrate in a state where the voltage is applied to at least one of the second electrode and the third electrode and the voltage is not applied to the first electrode, and the thin film deposited on the substrate may be etched in a state where the voltage is applied to at least one of the second electrode and the third electrode and the voltage is applied to the first electrode.

In some embodiments, the second electrode may comprise a magnet, and the third electrode may comprise a tube-shaped magnet enclosing a circumference of a space between the first electrode and the second electrode.

In some embodiments, the thin film forming apparatus may further comprise a target disposed on the second electrode. In this case, the target may contain a chalcogenide compound.

Embodiments of the inventive concept also provide a thin film forming method comprising: providing a substrate having a depressed portion on the first electrode of a thin film forming apparatus; depositing the thin film in the depressed portion by a first process in which a deposition ratio of the thin film is superior to an etching ratio of the thin film; and etching the thin film by a second process in which an etching ratio of the thin film is superior to a deposition ratio of the thin film. Here, the first process and the second process are alternately repeated.

In some embodiments, the first process may comprise forming an overhang on the depressed portion, and the second process may comprise removing the overhang.

In other embodiments, the second process may be executed before the overhang is formed on the thin film during the first process.

In still other embodiments, the first process and the second process may be executed by an in-suit manner in a single chamber.

### BRIEF DESCRIPTION OF THE DRAWINGS

The accompanying drawings are comprised to provide a further understanding of the inventive concept, and are incorporated in and constitute a part of this specification. The drawings illustrate exemplary embodiments of the inventive concept and, together with the description, serve to explain principles of the inventive concept. In the drawings:

FIG. 1 is a diagram illustrating a thin film forming apparatus according to an embodiment of the inventive concept;

FIG. 2 is a circuit diagram illustrating an example of a memory cell array of a substrate illustrated in FIG. 1;

FIG. 3 is a plan view illustrating a part of the substrate illustrated in FIG. 1;

FIG. 4 is a sectional view taken along the line I-I′ of FIG. 3;

FIGS. 5A and 5B are explanatory diagrams illustrating operations when the thin film forming apparatus according to the embodiment of the inventive concept forms a thin film;

FIGS. 6A through 6C are explanatory diagrams illustrating a thin film forming method according to an embodiment of the inventive concept;

FIGS. 7A and 7B are explanatory diagrams illustrating a thin film forming method according to another embodiment of the inventive concept;

FIG. 8A is a diagram illustrating a process cycle of a thin film forming method according to an embodiment of the inventive concept; and

FIG. 8B is a diagram illustrating a process cycle of a thin film forming method according to another embodiment of the inventive concept.

### DETAILED DESCRIPTION OF PREFERRED EMBODIMENTS

Advantages and features of the inventive concept and methods of accomplishing the same may be understood more readily by reference to the following detailed description of preferred embodiments and the accompanying drawings. The exemplary embodiments of the inventive concept may, however, be embodied in many different forms and should not be construed as being limited to the embodiments set forth herein. Rather, these embodiments are provided so that this disclosure will be thorough and complete and will fully convey the scope of the inventive concept to those skilled in the art. Like reference numerals refer to like elements throughout the specification.

The terminology used herein is for the purpose of describing various embodiments only and is not intended to be limiting of exemplary embodiments. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments are described herein with reference to cross-sectional illustrations and/or plane illustrations that are schematic illustrations of idealized embodiments of exemplary embodiments. In drawings, the thickness of layers and regions is exaggerated to effectively describe technical details. Accordingly, variations from the shapes of the illustrations as a result, for example, of manufacturing techniques and/or tolerances, are to be expected. Thus, exemplary embodiments should not be construed as limited to the shapes of regions illustrated herein but are to include deviations in shapes that result, for example, from manufacturing. For example, an etching region illustrated as a rectangle will, typically, have rounded or curved features. Thus, the regions illustrated in the figures are schematic in nature and their shapes are not intended to illustrate the actual shape of a region of a device and are not intended to limit the scope of exemplary embodiments.

Hereinafter, a thin film forming apparatus and a thin film forming method according to exemplary embodiments of the inventive concept will be described in detail with reference to the accompanying drawings.

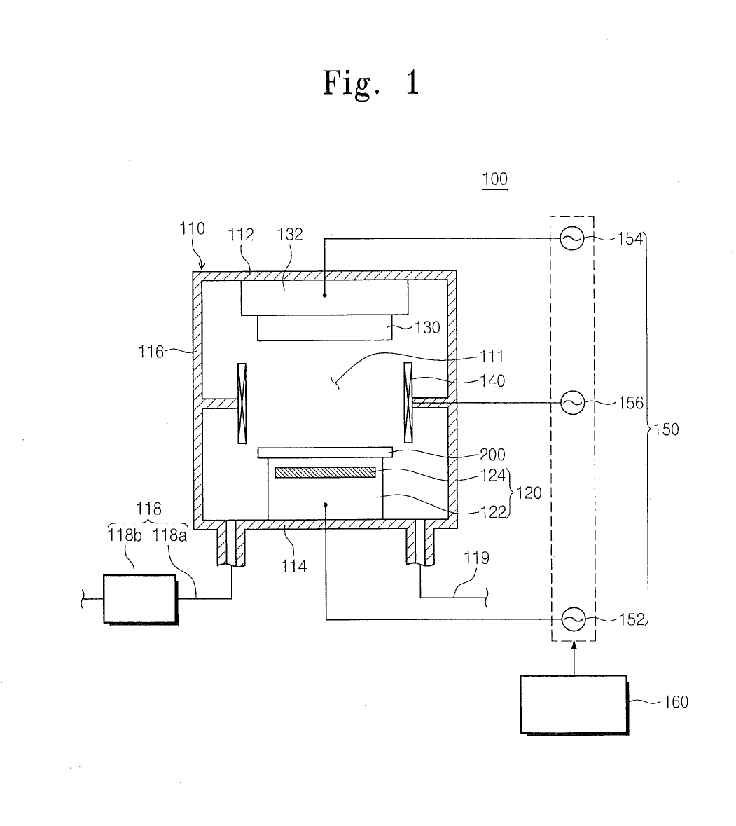

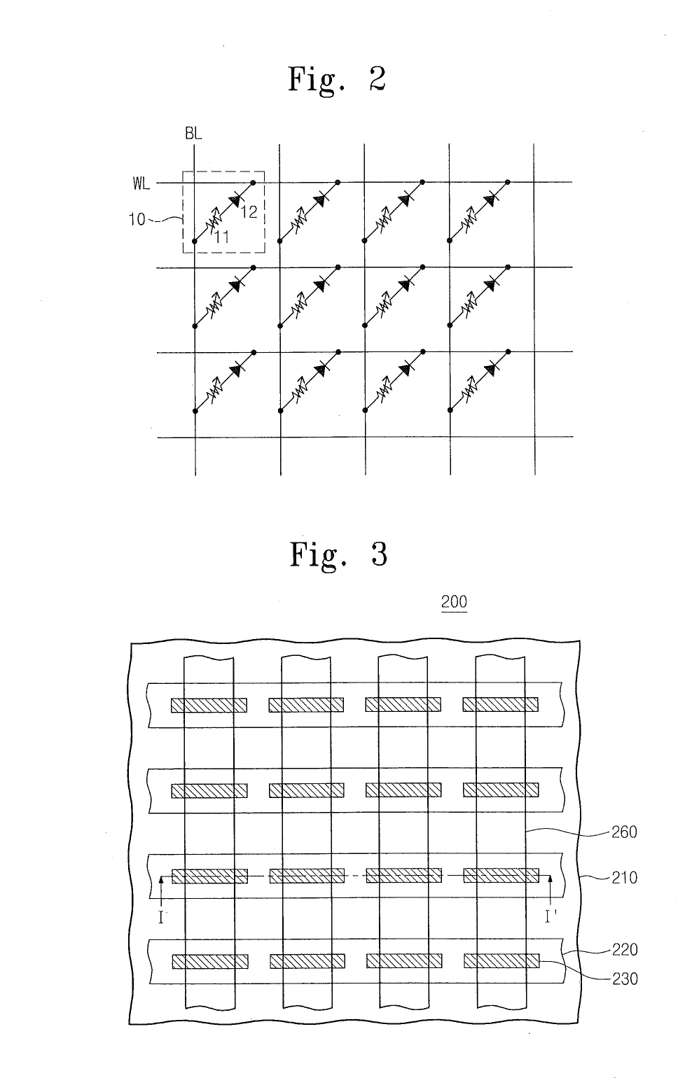

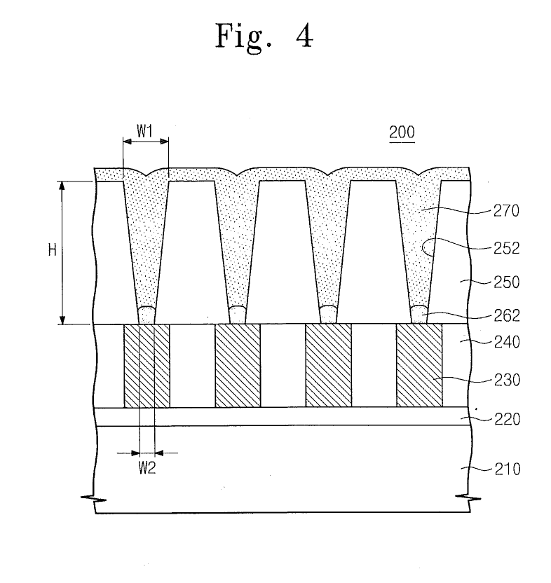

FIG. 1 is a diagram illustrating a thin film forming apparatus according to an embodiment of the inventive concept. FIG. 2 is a circuit diagram illustrating an example of a memory cell array of a substrate illustrated in FIG. 1. FIG. 3 is a plan view illustrating a part of the substrate illustrated in FIG. 1. FIG. 4 is a sectional view taken along the line I-I′ of FIG. 3.

Referring to FIG. 1, a thin film forming apparatus 100 forms a predetermined thin film on a substrate 200. The thin film forming apparatus 100 is an example of a sputtering apparatus or a physical vapor deposition apparatus.

The thin film forming apparatus 100 comprises a chamber 110, a substrate holding unit 120, a target 130, and a power applying unit 150.

The chamber 110 comprises an upper wall 112, a lower wall 114 facing the upper wall 112, and a sidewall 116 connecting the upper wall to the lower wall. The chamber 110 defines an internal space 111 where a thin film forming process is carried out. The internal space 111 becomes a vacuum atmosphere during the process. Therefore, the chamber 110 is provided with a pressure adjuster 118. The pressure adjuster 118 comprises a vacuum line 118a connected to the chamber 110 so as to communicate with the internal space 111. A vacuum pump 118b is equipped on the vacuum line 118a. The chamber 110 comprises a gas supply line 119 communicating with the internal space 111. The gas supply line 119 supplies a gas used for a process to the chamber 110. For example, the gas supply line 119 supplies at least one inert gas of an argon gas, a helium gas, and a neon gas to the chamber 110.

The substrate holding unit 120 holds the substrate 200. For example, the substrate holding unit 120 comprises a holding plate 122 having an upper surface on which the substrate 200 is placed. The holding plate 122 is disposed on the lower wall 114. The holding plate 122 has a substantially columnar shape. The substrate holding unit 120 comprises a first electrode 124. The first electrode 124 is disposed inside the holding plate 122. Moreover, the substrate holding unit 120 is capable of adjusting the temperature of the substrate 200. Therefore, the substrate holding unit 120 may further comprise a heater (not illustrated). The heater (not illustrated) comprises at least one heating plate that is disposed in the holding plate 122.

The target 130 is disposed on the upper wall 112 so as to face the holding unit 120. The target 130 has a substantially disk-like shape. The target 130 contains a thin film substance intended to be formed on the substrate 200. As an example, the target 130 contains a phase change substance such as a chalcogenide compound. For example, the phase change substance contains one of Ge—Sb—Te (GST), Ge—Bi—Te (GBT), As—Sb—Te, As—Ge—Sb—Te, Sn—Sb—Te, In—Sn—Sb—Te, Ag—In—Sb—Te, 5A group element-Sb—Te, 6A group element-Sb—Te, 5A group element-Sb—Se, 6A group element-Sb—Se, Ge—Sb—Te—Si, As—Sb—Te—Si, As—Ge—Sb—Te—Si, Sn—Sb—Te—Si, In—Sn—Sb—Te—Si, Ag—In—Sb—Te—Si, 5A group element-Sb—Te—Si, 6A group element-Sb—Te—Si, 5A group element-Sb—Se—Si, and 6A group element-Sb—Se—Si. When the target 130 contains the above-described phase change substance, the thin film forming apparatus 100 serves as an apparatus for forming a phase change film on the substrate 200 and the substrate 200 serves as a semiconductor substrate for forming a phase change random access memory (PRAM). On the other hand, a second electrode 132 is disposed between the target 130 and the upper wall 112. The second electrode 132 comprises a magnet. As an example, the second electrode 132 comprises a high flux uniform magnet. In this case, the magnet of the second electrode 132 is provided as a permanent magnet. As another example, the magnet of the second electrode 132 is provided as an electromagnet. The second electrode 132 is involved in generating plasma inside the internal space 111. Moreover, the second electrode 132 is involved with a deposition speed of the phase change film.

The thin film forming apparatus 100 may further comprise a third electrode 140. The third electrode 140 is disposed on the sidewall 114. The third electrode 140 is disposed so as to enclose around a space between the first electrode 124 and the second electrode 132. As an example, the third electrode 140 may comprise a magnet with a tube shape of which upper and lower portions are opened. In this case, the third electrode 140 generally comprises a magnet having a cross-section of a ring shape. As another example, the third electrode 140 may comprise magnets forming a plate shape disposed around a space between the first electrode 124 and the second electrode 132. The magnets of the third electrode 140 according to some embodiments may be provided as permanent magnet. Alternatively, the magnets of the third electrode 140 may be provided as an electromagnet. In this case, the third electrode 140 may be provided as a coil form enclosing the chamber 110 in the outside of the chamber 110.

A power applying unit 150 applies a voltage to the first electrode 124 and the second electrode 132. When the third electrode 140 is comprised, the power applying unit 150 applies a voltage to the third electrode 140. For example, the power applying unit 150 comprises a first applying section 152, a second applying section 154, and a third applying section 156. The first applying section 152 applies a voltage to the first electrode 124 of the substrate holding unit 120 and the second applying section 154 applies a voltage to the second electrode 132. The third applying section 156 applies a voltage to the third electrode 140. Here, the first to third applying sections 152, 154, and 156 apply various types of voltages to the first to third electrodes 124, 132, and 140, respectively. As an example, the first applying section 152 applies a bias voltage to the first electrode 124. The second applying section 154 applies one of an AC voltage, a DC voltage, and a bias voltage to the second electrode 132. The third applying section 156 applies one of an AC voltage and a DC voltage to the third electrode 140. As another example, at least one of the first to third applying sections 152, 154, and 156 is configured to apply a RF voltage, an ECR (Electro Cyclotron Resonance), and a microwave.

A control unit 160 controls the power applying unit 150. For example, the control unit 160 can independently control the first applying section 152, the second applying section 154, and the third applying section 156. Therefore, the power applying unit 150 can independently supply voltages to the first electrode 124, the second electrode 132, and the third electrode 140. Detailed processes of controlling the power applying unit 150 by the control unit 160 will be described below.

Next, the substrate 200 will be described in detail. In the illustrated embodiment of the inventive concept, a case where the substrate 200 comprises a memory device comprising memory cells with a variable resistance pattern will be described as an exemplary case. In the illustrated embodiment of the inventive concept, moreover, a case of selecting the phase change substance in the variable resistance pattern will be described. However, the technical spirit of the inventive concept is, of course, not limited thereto.

Referring to FIG. 2, the substrate 200 comprises a memory cell array having memory cells 10 arranged in a matrix form. The memory cells 10 each comprise a variable resistance element 11 and a selection element 12. The variable resistance element 11 and the selection element 12 are disposed between a bit line BL and a word line WL. The state of the variable resistance element 11 is determined depending on the amount of current supplied through the word line WL. The selection element 12 is disposed between the variable resistance element 11 and the word line WL. The current supplied to the variable resistance element 11 by the selection element 12 is controlled by the voltage of the word line WL. The selection element 12 may be a diode. Alternatively, the selection element 12 may be a MOS transistor or a bipolar transistor.

Referring to FIGS. 3 and 4, the substrate 200 comprises a silicon wafer 210. The silicon wafer 210 comprises conductive patterns 220 extending in one direction. The conductive pattern 220 comprises the word lines WL described above with reference to FIG. 2. The conductive pattern 220 may be a line doped with impurities. The silicon wafer 210 may further comprise a selection element (not illustrated) connected to the conductive pattern 220. A first interlayer insulating film 240 comprising lower electrodes 230 is disposed on the silicon wafer 210. The lower electrodes 230 are separated from each other on the conductive pattern 220. The lower electrodes 230 extend in the first direction. A second interlayer film 250 is disposed on the first interlayer insulating film 240. The second interlayer insulating film 250 has depressed portions 252 exposing the lower electrode 230. As an example, each of the depressed portions 252 is a contact hole. As another example, the depressed portion 252 is a trench formed in a direction intersecting the first direction. In this case, the depressed portion 252 has a large aspect ratio. For example, the height H of the depressed portion 252 is larger than that of the upper width W1 and the lower width W2 of the depressed portion 252. The upper width W1 is larger than the lower width W2.

A variable resistance pattern is disposed on the substrate 200. For example, the silicon wafer 210 comprises a phase change film 270 formed in the depressed portions 252. The phase change film 270 is connected to the lower electrode 230. The phase change film 270 has a program volume region 262. The program volume region 262 is formed so as to be adjacent to the lower electrode 230. A protective film (not illustrated) is disposed between the lower electrode 230 and the phase change film 270. The protective film may further be disposed between the second interlayer insulating film 250 and the phase change film 270. The protective film is capable of preventing heat loss of the phase change film 270. On the other hand, the phase change film 270 contains a phase change substance such as a chalcogenide substance. For example, the phase change film 270 contains one of Ge—Sb—Te (GST), Ge—Bi—Te (GBT), As—Sb—Te, As—Ge—Sb—Te, Sn—Sb—Te, In—Sn—Sb—Te, Ag—In—Sb—Te, 5A group element-Sb—Te, 6A group element-Sb—Te, 5A group element-Sb—Se, 6A group element-Sb—Se, Ge—Sb—Te—Si, As—Sb—Te—Si, As—Ge—Sb—Te—Si, Sn—Sb—Te—Si, In—Sn—Sb—Te—Si, Ag—In—Sb—Te—Si, 5A group element-Sb—Te—Si, 6A group element-Sb—Te—Si, 5A group element-Sb—Se—Si, and 6A group element-Sb—Se—Si. Moreover, the phase change film 270 may be doped with silicon or nitrogen in order to improve the resistance characteristics.

The phase change film 270 may be formed using the thin film forming apparatus 100 described above with reference to FIG. 1. The process of forming the phase change film 270 using the thin film forming apparatus 100 is described below.

Hereinafter, the thin film forming method according to an embodiment of the inventive concept will be described in detail. The thin film forming method described herein according to an embodiment of the inventive concept is realized by the thin film forming apparatus described with reference to FIG. 1. Accordingly, the duplicated details of the above-described thin film forming apparatus are omitted or simplified. In this embodiment of the inventive concept, a case where a process of forming the phase change film is completed in three steps will be described. However, the kinds of thin films formed according to the inventive concept and the number of processes are not limited thereto.

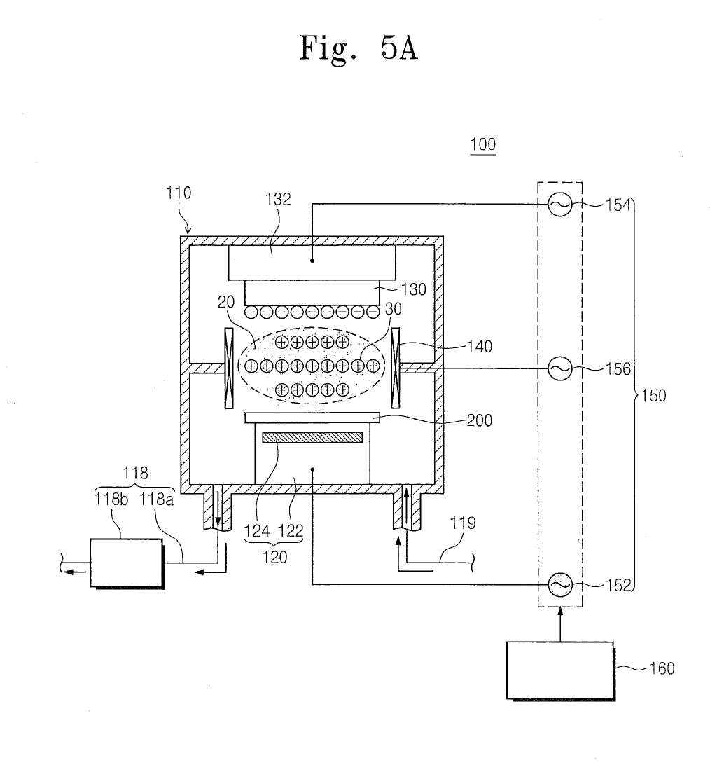

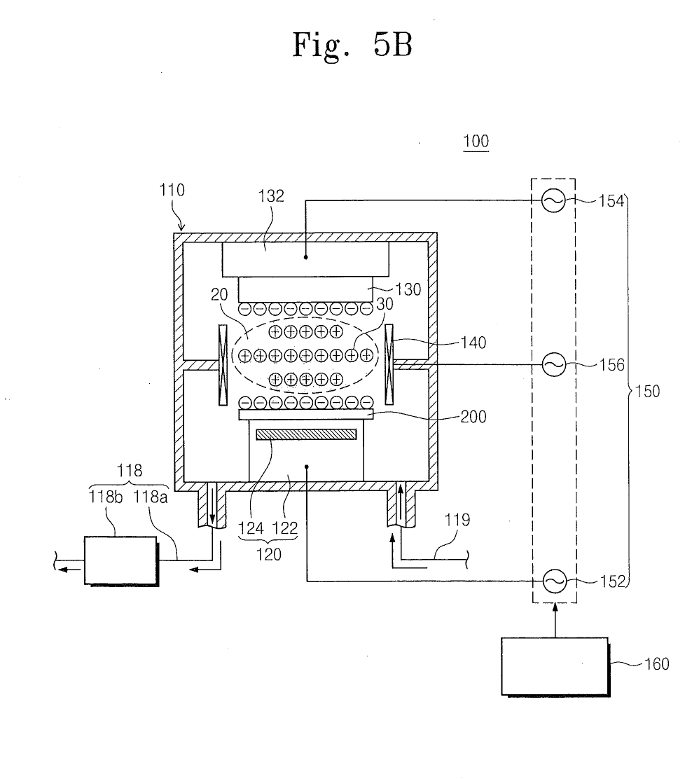

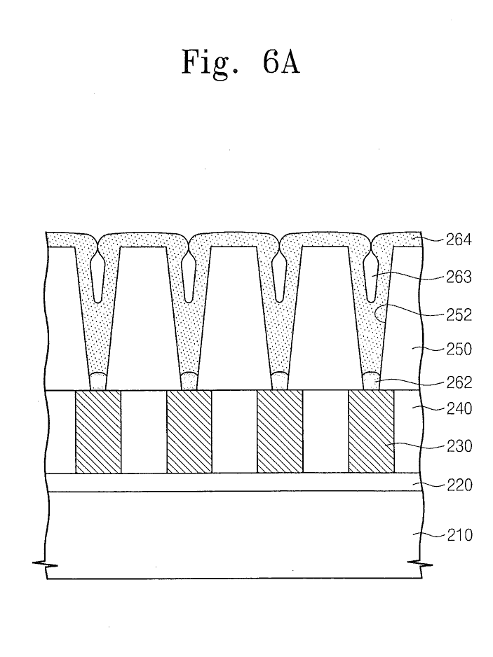

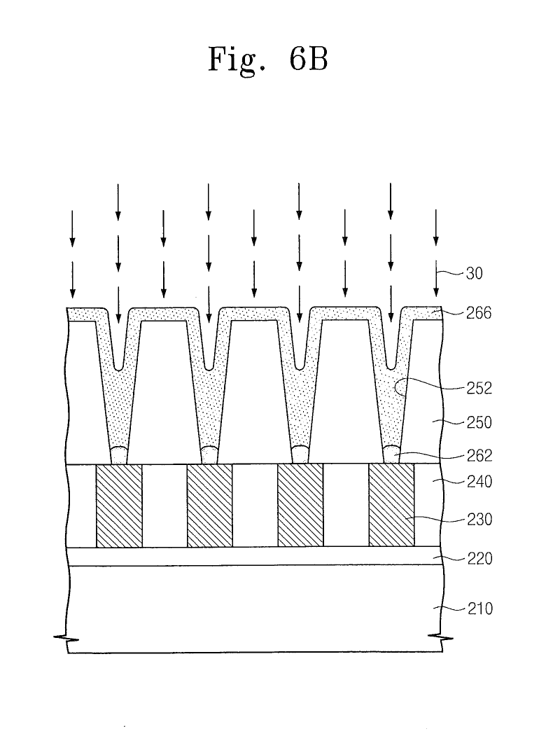

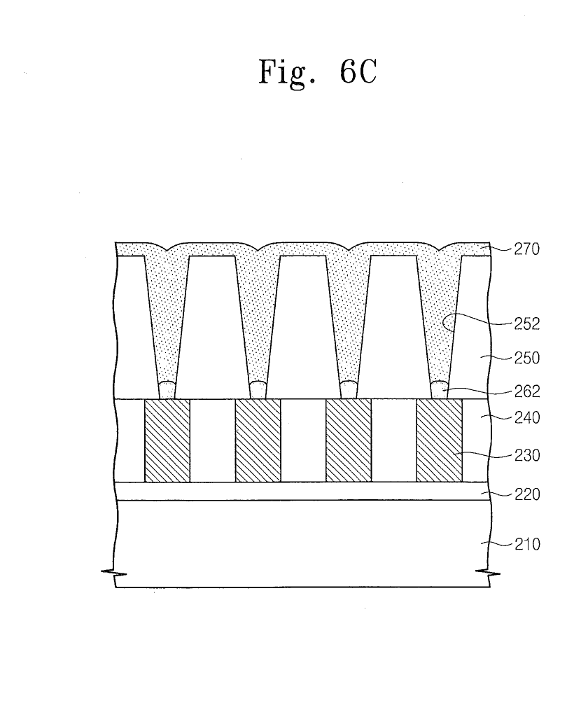

FIGS. 5A and 5B are explanatory diagrams illustrating the process of forming a thin film by the thin film forming apparatus according to an embodiment of the inventive concept. FIGS. 6A through 6C are explanatory diagrams illustrating a thin film forming method according to an embodiment of the inventive concept.

Referring to FIGS. 5A and 6A, the substrate 200 is prepared. For example, the process of preparing the substrate 200 comprises the process of preparing the substrate 200 described above with reference to FIGS. 3 and 4. In this case, the substrate 200 corresponds to a substrate before the phase change film 270 (see FIG. 4) is formed. Accordingly, the substrate 200 comprises a semiconductor substrate 210 and the conductive pattern 220, the first interlayer insulating film 240, and the second interlayer insulating film 250 stacked sequentially on the semiconductor substrate 210. The first interlayer insulating film 240 comprises the lower electrode 230 and the second interlayer insulating film 250 comprises the depressed portions 252 exposing the lower electrode 230.

The substrate 200 is carried in the chamber 110 of the thin film forming apparatus 100. The substrate 200 is loaded on the holding plate 122 of the substrate holding unit 120. The substrate 200 is heated at a processing temperature set in advance in the heater (not illustrated). The pressure adjuster 118 adjusts the pressure of the chamber 110 to a processing pressure set in advance. The vacuum pump 118b equipped on the vacuum line 118a may be activated. Accordingly, the internal space 111 of the chamber 110 may satisfy a vacuum atmosphere of the pressure set in advance.

A first process of depositing a thin film on the substrate 200 is executed. For example, the first process is a process satisfying a first process condition that a deposition ratio of the thin film is higher than an etching ratio of the thin film. For example, the gas supply line 119 supplies the inert gas 30 to the chamber 110. The inert gas 30 comprises one of an argon gas, a helium gas, and a neon gas. The control unit 160 can control the second applying section 154 of the power applying unit 150 so as to apply a voltage to the second electrode 132. On the other hand, the control unit 160 can control the first applying section 152 of the voltage applying unit 150 so as not to apply a voltage to the first electrode 124 of the substrate holding unit 120. Additionally, the control unit 160 can control the third applying section 156 so as to apply a voltage to the third electrode 140. In this case, the second applying section 154 can apply a negative (−) DC voltage to the second electrode 132 and the third applying section 156 can apply an AC voltage to the third electrode 140. In this way, plasma 20 is formed in the internal space 111 of the chamber 110. At this time, the plasma 20 is focused by the third electrode 140. Accordingly, the plasma 20 becomes highly dense and uniform by the third electrode 140.

The positively charged inert gas 30 is moved to the target 130 by the second electrode 132 of which negative (−) electrons are charged. The collision of the inert gas 30 with the target 130 results in separating the phase change substance of the target 130 from the target 130. At this time, since the voltage is not applied to the first electrode 124, the possibility that the inert gas 30 moves toward the substrate 200 is low. In this case, the deposition ratio of the thin film by the phase change substance is higher than the etching ratio of the thin film by the inert gas 30. Accordingly, a phase change film 264 filling the depressed portions 252 is deposited on the substrate 200. At this time, since the thin film forming apparatus 100 is a sputtering apparatus, the step coverage of the phase change film 264 may deteriorate. Accordingly, since the phase change film 264 forms an overhang at the upper portion of the depressed portion 252, a void 263 may be formed in the depressed portion 252.

On the other hand, in the first process, the program volume region 262 is formed so as to be adjacent to the lower electrode 230. The program volume region 262 is a region where the phase change is made when the voltage is applied to the lower electrode 230. The program volume area 262 is advantageous for the phase change process of effectively forming the uniform composition. Accordingly, it is desirable that the program volume region 262 is completely formed only by one process. In order to achieve this, the first process is executed so that the depressed portion 252 is sufficiently filled with the phase change film 264 to form at least the program volume region 262.

Referring to FIGS. 5B and 6B, a second process of etching the thin film on the substrate 200 is executed. For example, the second process is a process satisfying a second process condition that the etching ratio of the thin film is higher than the deposition ratio of the thin film. For example, in a state where the voltage is applied between the second electrode 132 and the third electrode 140, the control unit 160 controls the first applying section 152 of the power applying unit 150 so as to apply the voltage to the first electrode 124 of the substrate holding unit 120. At this time, the first applying section 152 applies a negative bias voltage to the substrate holding unit 120. In this case, the positively charged inert gas 30 in the chamber 110 is guided toward the substrate 200 by the first electrode 124 of which the negative electrons are charged. Accordingly, the possibility that the inert gas 30 moves toward the substrate 200 becomes higher. At this time, the inert gas 30 collides with the substrate 200 mainly in a vertical direction with respect to the substrate 200. In this case, the etching ratio of the thin film by the inert gas 30 is higher than the deposition ratio of the thin film by the phase change substance. Accordingly, the inert gas 30 etches the phase change film 264 (see FIG. 6A) to form a phase change film 266 in which the overhangs are removed.

Referring to FIGS. 5A and 6C, the first process described above with reference to FIG. 5A is again executed. For example, in a state where the voltage is applied to the first to third electrodes 124, 132, and 140, the control unit 160 controls the first applying section 152 so as not to apply the voltage to the first electrode 124. Accordingly, the thin film deposition process is more predominantly executed on the substrate 200. However, since the phase change film is formed in parts of the depressed portions 252 in the previous process, a phase change film 270 completely filling the depressed portions 252 having no overhang is formed in the first process. Alternatively, during the first process, the phase change film in which the overhangs are formed in the depressed portions 252 may be formed again. In this case, the phase change film 270 completely forming the depressed portions 252 having no overhang can be formed by repeatedly executing the first process after the second process described above with reference to FIG. 6B until the overhang is not formed.

The case where the phase change film 270 is formed by turning ON/OFF the voltage to be applied to the first electrode 124 of the substrate holding unit 120 in the state where the voltage is applied to the second and third electrodes 132 and 140 has been described as an example of the thin film forming method according to an embodiment of the inventive concept. According to a modified example of the above-described forming method, however, the phase change film 270 may be formed by adjusting the amplitude of the voltage to be applied to the first to third electrodes 124, 132, and 140. More specifically, the phase change film 270 may be formed by adjusting the amplitude of the voltage to be applied to at least one of the first electrode 124 and the second electrode 132 in the state where a predetermined voltage is applied to the first to third electrodes 124, 132, and 140.

According to the above-described thin film forming method of the embodiment of the inventive concept, the depressed portions are filled with the thin film by alternately forming the thin film so as to form the overhang and etching the thin film so as to remove the overhang by an in-situ manner in the single chamber 110. In this way, the thin film can be formed effectively in the depressed portions with the relatively large aspect ratio according to the embodiment of the inventive concept.

Since the thin film is formed by the sputtering process in the thin film forming method according to an embodiment of the inventive concept, the thin film can be formed effectively in the depressed portions with the large aspect ratio at the relatively low temperature.

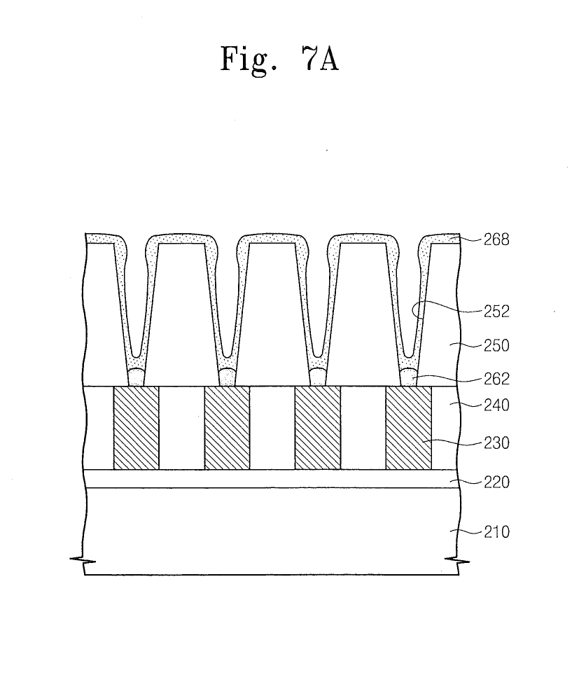

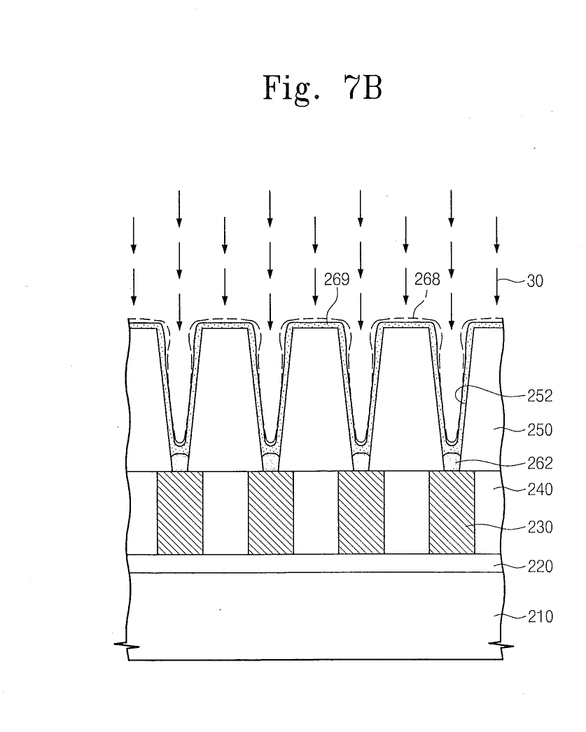

Hereinafter, a thin film forming method according to another embodiment of the inventive concept will be described in detail, referring again to FIGS. 5A and 5B. The duplicated details of the above-described thin film forming apparatus are omitted or simplified. Moreover, the duplicated details of the thin film forming process described with reference to FIGS. 5A and 5B and FIGS. 6A through 6C are omitted or simplified. FIGS. 7A and 7B are explanatory diagrams illustrating a thin film forming method according to another embodiment of the inventive concept.

Referring to FIGS. 5A and 7A, a third process of depositing a thin film on the substrate 200 under a third process condition is executed. The third process condition is nearly the same condition as the first process condition. For example, the third process may be executed under a third process condition that a deposition ratio of the thin film is higher than an etching ratio of the thin film. For example, the control unit 160 controls the second and third applying sections 154 and 156 of the power applying unit 150 so as to apply a voltage to the second electrode 132 and the third electrode 140, respectively, and controls the first applying section 152 of the power applying unit 150 so as not to apply a voltage to the first electrode of the substrate holding unit 110. In this way, a phase change film 268 filling the depressed portions 252 is formed.

Referring to FIGS. 5B and 7B, a fourth process of etching the thin film on the substrate 200 is executed under a fourth process condition. The fourth process is a step satisfying the fourth process condition which is nearly the same as the second process condition. For example, the fourth process condition is a condition that the etching ratio of the thin film is higher than the deposition ratio of the thin film. For example, the control unit 160 controls the first to third applying sections 152, 154, and 156 of the power applying unit 150 so as to apply a voltage to the second electrode 132, the third electrode 140, and the first electrode 124 of the substrate holding unit 120. In this case, the inert gas 30 in the chamber 110 etches the phase change film 268 to form an etched phase change film 269. At this time, the fourth process is controlled so as not to excessively etch the phase change film 268 by the inert gas 30 and expose the second inter-layer insulating film 250.

Here, the above-described third and fourth processes may be adjusted so as not to form the overhang on the depressed portions 252. More specifically, the phase change film 268 is formed in the depressed portions 252 in the third process and the phase change film 269 formed by etching the phase change film 268 is formed in the fourth process. No overhang may be formed on the depressed portion 252 by executing the fourth process before the overhang is formed in the depressed portion 252 during the third process. In this way, when the third and fourth processes are alternately repeated, the phase change film 270 (FIG. 4) is completely formed, while the depressed portions 252 are gradually filled with the phase change substance without forming the overhang.

The case where the phase change film 270 is formed by turning ON/OFF the voltage to be applied to the first electrode 124 of the substrate holding unit 120 in the state where the voltage is applied to the second and third electrodes 132 and 140 has been described as an example of the thin film forming method according to another embodiment of the inventive concept. However, according to a modified example of the above-described forming method, the phase change film 270 may be formed by adjusting the amplitude of the voltage to be applied to the first to third electrodes 124, 132, and 140. More specifically, the phase change film 270 may be formed by adjusting the amplitude of the voltage to be applied to at least one of the first electrode 124 and the second electrode 132 in the state where a predetermined voltage is applied to the first to third electrodes 124, 132, and 140.

In the above-described thin film forming method according to another embodiment of the inventive concept, the depressed portions are filled with the thin film while the deposition ratio of the thin film in an in-situ manner is changed in the single chamber 110. In this way, the thin film can be formed effectively in the depressed portions with the relatively large aspect ratio according to the inventive concept.

Since the thin film is formed by the sputtering process in the thin film forming method according to another embodiment of the inventive concept, the thin film can be formed effectively in the depressed portions with the large aspect ratio at the relatively low temperature.

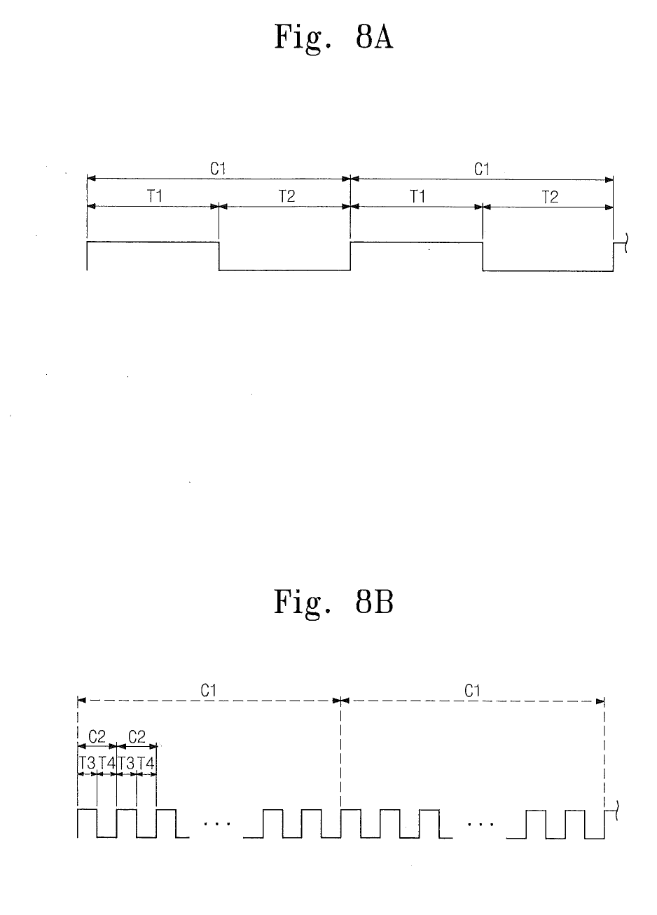

Next, the thin film forming method according to an embodiment of the inventive concept will be compared to the thin film forming method according to another embodiment. FIG. 8A is a diagram illustrating a process cycle of the thin film forming method according to an embodiment of the inventive concept. FIG. 8B is a diagram illustrating a process cycle of a thin film forming method according to another embodiment of the inventive concept.

Referring to FIG. 8A, a first process cycle C1 is constituted by a time (hereinafter, referred to as a first time T1), in which the above-described first process is executed, and a time (hereinafter, referred to as a second time T2), in which the second process is executed. The thin film forming process is completed by repeatedly executing the thin film forming method according to an embodiment of the inventive concept during the first process cycle C1.

Referring to FIG. 8B, a second process cycle C2 is constituted by a time (hereinafter, referred to as a third time T3), in which the above-described third process is executed, and a time (hereinafter, referred to as a fourth time T4), in which the fourth process is executed. The thin film forming process is completed by repeatedly executing the thin film forming method according to another embodiment of the inventive concept during the second process cycle C2.

When FIGS. 8A and 8B are compared to each other, the first process cycle C1 is longer than the second process cycle C2. For example, as described above, the thin film is deposited during the formation of the overhang in the thin film forming method according to an embodiment of the inventive concept. On the contrary, the thin film is deposited during non-formation of the overhang in the thin film forming method according to another embodiment of the inventive concept. Therefore, the first time T1 is longer than the third time T3, since the first time T1 is required to be longer in order to form the overhangs. Moreover, the second time T2 is longer than the fourth time T4, since the second time T2 is required to be longer in order to remove the overhangs. As a consequence, the first process cycle C1 is executed once, while the second process cycle C2 is executed multiple times. The adjustment of the process cycles C1 and C2 can be realized by adjusting a shift period of the application of a voltage and non-application of a voltage to the first electrode 124 by the control unit 160 described above with reference to FIG. 1.

According to the embodiments of the inventive concept, the thin film forming apparatus can independently control voltages to be applied to the first electrode, second electrode, and third electrode. Accordingly, it can form the thin film on the substrate while changing the deposition rate of the thin film.

According to embodiments of the inventive concept, the thin film forming apparatus can form the thin film on the substrate while changing the deposition rate of the thin film by the sputtering way. Accordingly, the thin film forming apparatus can form the thin film having good step coverage at a low temperature.

According to embodiments of the inventive concept, the thin film forming method can form the thin film on the substrate while adjusting the deposition speed and the etching speed of the thin film. Accordingly, it can form the thin film in the depressed portions having a large aspect ratio.

According to embodiments of the inventive concept, the thin film forming method can form the thin film on the substrate while changing the deposition rate of the thin film by the sputtering way. Accordingly, the thin film forming method can form the thin film having good step coverage at a low temperature.

The detailed description has been made just as an example of the inventive concept. The foregoing details have been described just as preferred embodiments of the inventive concept and a variety of combinations, modifications, and changes of the inventive concept may be made. That is, it should be apparent to those skilled in the art that the modification and changes of the inventive concept may be made within the scope of the equivalents and/or the techniques or the knowledge in the art. The embodiments have been described to explain the preferred examples of the inventive concept. The inventive concept may be embodied in forms known to the art and specific applied fields and applications of the inventive concept may be changed. Accordingly, the detailed description of the embodiments is not intended to limit the inventive concept. The appended claims should be construed as comprising other embodiments.

1. A thin film forming apparatus, comprising:
a chamber having an internal space configured to execute a thin film forming process on a substrate;
a first electrode provided for etching a thin film formed on the substrate;
a second electrode provided for forming plasma in the internal space;
a third electrode provided for focusing the plasma; and
a control unit controlling a voltage to be applied to the first through third electrodes.

2. The thin film forming apparatus of claim 1, wherein:
the chamber comprises an upper wall, a lower wall facing the upper wall, and a sidewall connecting the upper wall to the lower wall,
the first electrode is disposed on the lower wall to load the substrate,
the second electrode is disposed on the upper wall, and
the third electrode is disposed on the sidewall.

3. The thin film forming apparatus of claim 1, further comprising first through third applying sections connected to the first through third electrodes, respectively, to apply the voltage to the first through third electrodes,
wherein the control unit independently controls each of the first through third applying sections.

4. The thin film forming apparatus of claim 1, wherein the thin film is deposited on the substrate in a state where the voltage is applied to at least one of the second electrode and the third electrode and the voltage is not applied to the first electrode, and
the thin film deposited on the substrate is etched in a state where the voltage is applied to at least one of the second electrode and the third electrode and the voltage is applied to the first electrode.

5. The thin film forming apparatus of claim 1, wherein the second electrode comprises a magnet, and
the third electrode comprises a tube-shaped magnet enclosing a circumference of a space between the first electrode and the second electrode.

6. The thin film forming apparatus of claim 1, further comprising a target disposed on the second electrode,
wherein the target contains a chalcogenide compound.

7.-10. (canceled)

11. A thin film forming apparatus, comprising:
a chamber;
a substrate holding unit disposed within the chamber, wherein the substrate holding unit comprises a holding plate having an upper surface that receives a substrate thereon, and a first electrode within the holding plate;
a target disposed within the chamber in spaced-apart relationship with the substrate holding unit;
a second electrode disposed within the chamber between the target and a wall of the chamber;
a third electrode that encloses a space between the first and second electrodes; and
a power applying unit configured to apply a voltage to the first, second, and third electrodes.

12. The thin film forming apparatus of claim 11, wherein the power applying unit applies a bias voltage to the first electrode; one of an AC voltage, DC voltage, or bias voltage to the second electrode; and one of an AC voltage or DC voltage to the third electrode.

13. The thin film forming apparatus of claim 11, wherein the target has a substantially disk-like shape.
